(19) United States
(12) Patent Application Publication
(10) Pub. No.: US 2026/0344507 A1
(43) Pub. Date: Oct. 29, 2026

(54) MIXED ARRANGEMENTS OF LIGHT-EMITTING DIODE STRUCTURES IN LIGHT-EMITTING DIODE DEVICES

(71) Applicant: CreeLED, Inc., Durham, NC (US)

(72) Inventors: Colin Blakely, Raleigh, NC (US); David Suich, Durham, NC (US); Scott Wegner, Boulder, CO (US); Robert Wilcox, Rolesville, NC (US)

(21) Appl. No.: 19/187,498

(22) Filed: Apr. 23, 2025

(51) Int. Cl. H10W 90/00; H10H 20/85; H10H 20/851; H10H 20/855; H10H 20/857; H10H 29/24; H10H 29/85

(52) U.S. Cl. CPC H10W 90/00; H10H 20/8508; H10H 20/8512; H10H 20/855; H10H 20/857; H10H 29/24; H10H 29/8508; H10H 29/857

(57) ABSTRACT

Light-emitting diode (LED) devices and more particularly mixed arrangements of LED structures in LED devices are disclosed. LED structures include different types of LED emitters, including LED packages and bare LED chips, assembled in a common LED device. The bare LED chips are mounted to underlying submounts, such as printed circuit boards, without intervening package elements, such as package submounts and/or lead frame structures. The bare LED chips are configured to exhibit increased thermal dissipation to the underlying submounts. Exemplary LED devices include mixed arrangements of LED emitters configured to selectively provide multiple wavelengths of light. Exemplary applications include horticulture lighting devices where peak wavelengths and emission profiles may be selectively adjusted by independently controlling various LED emitters of the mixed arrangements.

### FIELD OF THE DISCLOSURE

The present disclosure relates to light-emitting diode (LED) devices, and more particularly to mixed arrangements of LED structures in LED devices.

### Background

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays, lighting devices for general illumination, and horticulture applications, among others.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED technology is increasingly being developed for horticulture applications where emissions are provided to stimulate photosynthesis in growing plants. LED manufacturers for horticulture applications must balance multiple application tradeoffs of efficacy, longevity, spectral optimization, and optical distribution.

The art continues to seek improved LEDs and solid-state lighting devices having desirable illumination characteristics capable of overcoming challenges associated with conventional lighting devices.

### Summary

The present disclosure relates to light-emitting diode (LED) devices, and more particularly to mixed arrangements of LED structures in LED devices. LED structures include different types of LED emitters, including LED packages and bare LED chips, assembled in a common LED device. The bare LED chips are mounted to underlying submounts, such as printed circuit boards, without intervening package elements, such as package submounts and/or lead frame structures. The bare LED chips are configured to exhibit increased thermal dissipation to the underlying submounts. Exemplary LED devices include mixed arrangements of LED emitters configured to selectively provide multiple wavelengths of light. Exemplary applications include horticulture lighting devices where peak wavelengths and emission profiles may be selectively adjusted by independently controlling various LED emitters of the mixed arrangements.

In one aspect, an LED device comprises: a submount comprising a printed circuit board; a first LED emitter on the submount, the first LED emitter comprising an LED package with a first LED chip configured to provide light having a first peak wavelength; and a second LED emitter on the submount, the second LED emitter comprising a second LED chip that forms a bare LED chip mounted to the submount, the second LED chip configured to provide light having a second peak wavelength that is different than the first peak wavelength, the first peak wavelength and the second peak wavelength being in a range from 630 nanometers (nm) to 780 nm. The LED device may further comprise: an LED driver on the submount, the LED driver configured to electrically activate the first LED emitter and the second LED emitter independently of one another; and one or more electrical connectors on the submount, the one or more electrical connectors configured to receive an external electrical connection for the LED driver.

In certain embodiments, the LED package of the first LED emitter comprises a lens configured to provide a first emission pattern that is different from a second emission pattern provided by the second LED emitter. In certain embodiments, the first LED emitter comprises package bonding pads bonded to the submount, and the second LED emitter comprises at least one wire bond bonded between the second LED chip and the submount. In certain embodiments, the first LED emitter comprises package bonding pads bonded to the submount, and the second LED chip of the second LED emitter is flip-chip mounted to the submount. The LED device may further comprise: a third LED emitter on the submount, the third LED emitter comprising an LED package with a third LED chip configured to provide light having a third peak wavelength that is different than the first peak wavelength and the second peak wavelength; and a fourth LED emitter on the submount, the fourth LED emitter comprising an LED package with a fourth LED chip and a lumiphoric material. The LED device may further comprise: a third LED emitter on the submount, the third LED emitter comprising an LED package with a third LED chip configured to provide light having a third peak wavelength that is different than the first peak wavelength and the second peak wavelength; and a fourth LED emitter on the submount, the fourth LED emitter comprising a fourth LED chip mounted to the submount and a lumiphoric material on the fourth LED chip. The LED device may further comprise a third LED emitter on the submount, the third LED emitter comprising a third LED chip mounted to the submount and a lumiphoric material on the third LED chip, the lumiphoric material being positioned to cover the third LED emitter and the second LED emitter. The LED device may further comprise a lens on the second LED chip and on a portion of the submount laterally adjacent the second LED chip. The LED device may further comprise a light-altering material on the submount and laterally surrounding a perimeter of the second LED chip, the light-altering material comprising a light-reflective material. In certain embodiments, the printed circuit board comprises a metal core and a dielectric layer on the metal core, wherein the second LED chip is mounted and electrically coupled to a trace of the printed circuit board, the trace forming part of a direct thermal and electrical path through the dielectric layer to the metal core.

In another aspect, an LED device comprises: a first printed circuit board; a second printed circuit board; a plurality of first emitters on at least one of the first printed circuit board and the second printed circuit board, each first emitter of the plurality of first emitters comprising an LED package with a first LED chip configured to provide light having a first peak wavelength; and a plurality of second emitters on at least one of the first printed circuit board and the second printed circuit board, each second emitter of the plurality of second emitters comprising a second LED chip that forms a bare LED chip mounted to the at least one of the first printed circuit board and the second printed circuit board, the second LED chip configured to provide light having a second peak wavelength that is different than the first peak wavelength, the first peak wavelength and the second peak wavelength being in a range from 630 nanometers (nm) to 780 nm.

The LED device may further comprise an LED driver configured to drive the plurality of first emitters and the plurality of second emitters. In certain embodiments, the LED driver is positioned on the first printed circuit board and the LED driver is electrically coupled to the second printed circuit board by at least one electrical connection that extends between the first printed circuit board and the second printed circuit board. In certain embodiments: the plurality of first emitters forms an array of the first emitters that extends across the first printed circuit board and the second printed circuit board; and the plurality of second emitters forms an array of the second emitters that extends across the first printed circuit board and the second printed circuit board. In certain embodiments, the plurality of first emitters are only on the first printed circuit board and the plurality of second emitters are only on the second printed circuit board. The LED device may further comprise a third printed circuit board and a plurality of third emitters that are only on the third printed circuit board, wherein each third emitter of the plurality of third emitters comprises a third LED chip with a turn-on voltage that is different than turn-on voltages of the plurality of first emitters and the plurality of second emitters. The LED device may further comprise a plurality of fourth LED emitters on the third printed circuit board, each fourth LED emitter of the plurality of fourth LED emitters comprising a fourth LED chip mounted to the submount and a lumiphoric material on the fourth LED chip, fourth LED chip have the same turn-on voltage as the third LED chip. In certain embodiments, the lumiphoric material covers the plurality of fourth LED emitters on the third printed circuit board. The LED device may further comprise a light-altering material that laterally surrounds a perimeter of the lumiphoric material on the third printed circuit board.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a top view of an exemplary light-emitting diode (LED) device that is populated with a plurality of the LED emitters configured to provide a plurality of peak wavelengths according to embodiments of the present disclosure.

FIG. 2A is a top view of an LED device that is similar to the LED device of FIG. 1 for embodiments where certain LED emitters embody LED chips that are mounted to the submount without packaging.

FIG. 2B is a cross-sectional view of a portion of the LED device of FIG. 2A taken along the sectional line 2B-2B of FIG. 2A.

FIG. 3A is a top view of an LED device that is similar to the LED device of FIGS. 2A and 2B for embodiments where the LED emitters embody LED chips that are flip-chip mounted to the submount without packaging.

FIG. 3B is a cross-sectional view of a portion of the LED device of FIG. 3A taken along the sectional line 3B-3B of FIG. 3A.

FIG. 4A is a top view of an LED device that is similar to the LED device of FIGS. 3A and 3B for embodiments where both of the LED emitters embody LED chips mounted to the submount without packaging.

FIG. 4B is a cross-sectional view of a portion of the LED device of FIG. 4A taken along the sectional line 4B-4B of FIG. 4A.

FIG. 5 is a cross-sectional view of an LED device that is similar to the LED device of FIGS. 4A and 4B for embodiments where at least one of the LED emitters further includes a lens.

FIG. 6 is a cross-sectional view of an LED device that is similar to the LED device of FIG. 5 for embodiments where the LED chip has a vertical chip structure.

FIG. 7 is a top view of an LED device that is similar to the LED device of FIGS. 2A and 2B for embodiments that include multiple submounts.

FIG. 8 is a top view of an LED device that is similar to the LED device of FIG. 7 with another arrangement of multiple submounts.

FIG. 9A is a top view of an LED device that is similar to the LED device of FIG. 8 for embodiments where the lumiphoric material extends across multiple ones of the LED emitters.

FIG. 9B is a cross-sectional view of a portion of the LED device of FIG. 9A taken along the sectional line 9B-9B of FIG. 9A.

FIG. 10A is a top view of an LED device that is similar to the LED device of FIGS. 9A and 9B for embodiments that further include a light-altering material.

FIG. 10B is a cross-sectional view of a portion of the LED device of FIG. 10A taken along the sectional line 10B-10B of FIG. 10A.

FIG. 10C is a cross-sectional view of a portion of the LED device of FIG. 10A taken along the sectional line 10B-10B of FIG. 10A for an alternative arrangement of the light-altering material and the lumiphoric material.

FIG. 11 is a cross-sectional view of a portion of an LED device that is similar to the LED device of FIGS. 2A and 2B for embodiments where the light-altering material is provided to laterally surround perimeter edges of the LED chips that emit red light.

FIG. 12 is a cross-sectional view of a portion of an LED device that is similar to the LED device of FIGS. 9A and 9B for embodiments where the lumiphoric material extends to cover the LED chip.

FIG. 13 is a top perspective view of an LED device similar to the LED device of FIGS. 2A and 2B for embodiments where the submount comprises a printed circuit board with a metal core and a top dielectric layer.

FIG. 14 is a top perspective view of an LED device similar to the LED device of FIG. 13 for embodiments where at least one of the traces forms a direct electrical and thermal path to the metal core.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to mixed arrangements of LED structures in LED devices. LED structures include different types of LED emitters, including LED packages and bare LED chips, assembled in a common LED device. The bare LED chips are mounted to underlying submounts, such as printed circuit boards, without intervening package elements, such aa package submounts and/or lead frame structures. The bare LED chips are configured to exhibit increased thermal dissipation to the underlying submounts. Exemplary LED devices include mixed arrangements of LED emitters configured to selectively provide multiple wavelengths of light. Exemplary applications include horticulture lighting devices where peak wavelengths and emission profiles may be selectively adjusted by independently controlling various LED emitters of the mixed arrangements.

Before delving into specific details for aspects of the present disclosure, an overview of various elements that may be included in exemplary LED devices is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds such as aluminum gallium indium phosphide (AlGaInP). The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

In the context of horticultural applications, primary chlorophyll absorption peaks exist in certain blue and red ranges, such as a range from 450 nm to 500 nm and in another range from 630 nm to 780 nm. In certain embodiments, LED devices according to the present disclosure are well suited for use as so-called photored devices that target specific red wavelength ranges in various horticultural applications. For example, the specific red wavelength ranges may include a peak wavelength in a range of 630 nm to 780 nm, or a range from 658 nm to 665 nm. In still further embodiments, LED devices according to the present disclosure include mixed arrangements of LED emitters, including combinations of bare LED chips and LED packages, configured to provide a variety of targeted wavelengths for various chlorophyll absorption peaks.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount or a lead frame structure.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Lead frame structures typically include electrically conductive leads that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

Encapsulant materials, such as silicone, epoxy, or polymethyl methacrylate (PMMA), among others, may be formed to encapsulate the LED chips over a submount or a lead frame structure. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Challenges exist in efficiently operating LED devices in various environments. By way of example, LED lighting devices for horticulture applications are selected so that LED devices with specific peak wavelengths are matched to specific primary chlorophyll absorption peaks of targeted crops. LED devices according to the present disclosure include mixed arrangements of LED emitters, including combinations of bare LED chips and LED packages, configured to provide a variety of selectable peak wavelengths for various chlorophyll absorption peaks. The mixed arrangement of LED emitters provides the ability to selectively change peak wavelengths in a horticulture environment to target different crops and/or provide different wavelengths of light during different stages of crop growth. The mixed arrangement of LED emitters in a common LED device provides further improvements in emission patterns, thermal management, and color mixing, among other improvements. Moreover, unpackaged or bare LED chips in the mixed arrangements may permit secondary optics, such as those in lighting fixtures, to be placed closer to these LED chips. Without having to clear dimensions of a package submount and corresponding package bonding materials, secondary optics may be provided with smaller form factors, thereby occupying reduced space with reduced material usage.

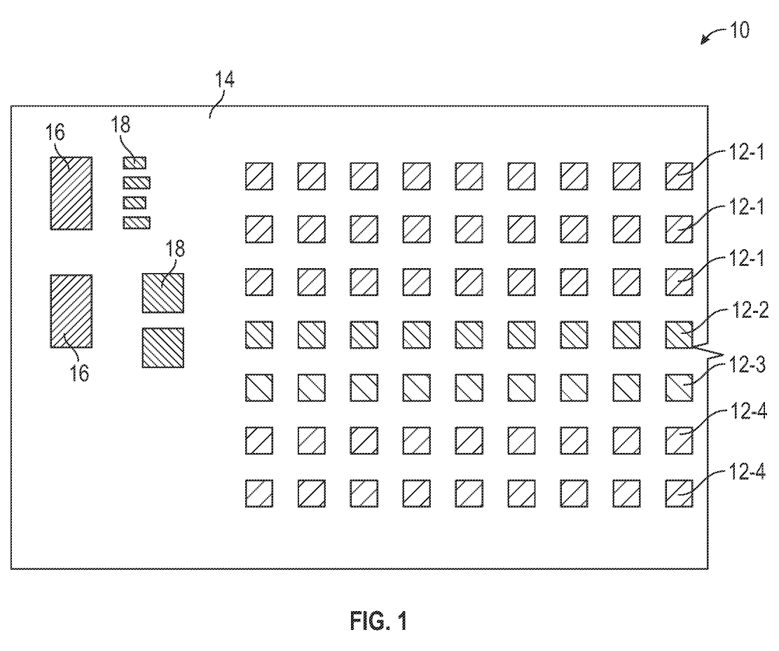

FIG. 1 is a top view of an exemplary LED device 10 that is populated with a plurality of the LED emitters 12-1 to 12-4 configured to provide a plurality of peak wavelengths according to embodiments of the present disclosure. By way of example, the LED emitters 12-1 may embody LED packages configured to provide a first peak wavelength in a red wavelength range, the LED emitters 12-2 may embody LED packages configured to provide a second peak wavelength that is different than the first peak wavelength but also in a red wavelength range, the LED emitters 12-3 may embody LED packages configured to provide a third peak wavelength in a blue wavelength range, and the LED emitters 12-4 may embody LED packages with lumiphoric materials configured to provide a wavelength-converted light, such as generally white light. As illustrated, the LED emitters 12-1 to 12-4 may collectively form an array on a surface of a common submount 14. In certain arrangements, LED emitters 12-1 to 12-4 of each type may be arranged together in rows as illustrated by FIG. 1. By way of example, the submount 14 may embody a printed circuit board with electrically conductive traces connected the LED emitters 12-1 to 12-4. One or more electrical connectors 16 may also be arranged on the submount 14 for receiving external electrical connections. Additionally, one or more other semiconductor devices 18, such as circuit elements that form an LED driver and/or LED controller, may be arranged on the submount 14. The LED driver formed by the semiconductor devices 18 may be electrically connected to the electrical connectors 16 and the LED emitters 12-1 to 12-4. In certain embodiments, each type of the LED emitters 12-1 to 12-4 may be electrically coupled as a separate string that is electrically coupled to the LED driver so that an output of the LED driver provides individual control for a variety of target emission wavelengths. By way of example, the LED device 10 may represent a lighting board that resides in a lighting fixture, such as one for horticulture applications.

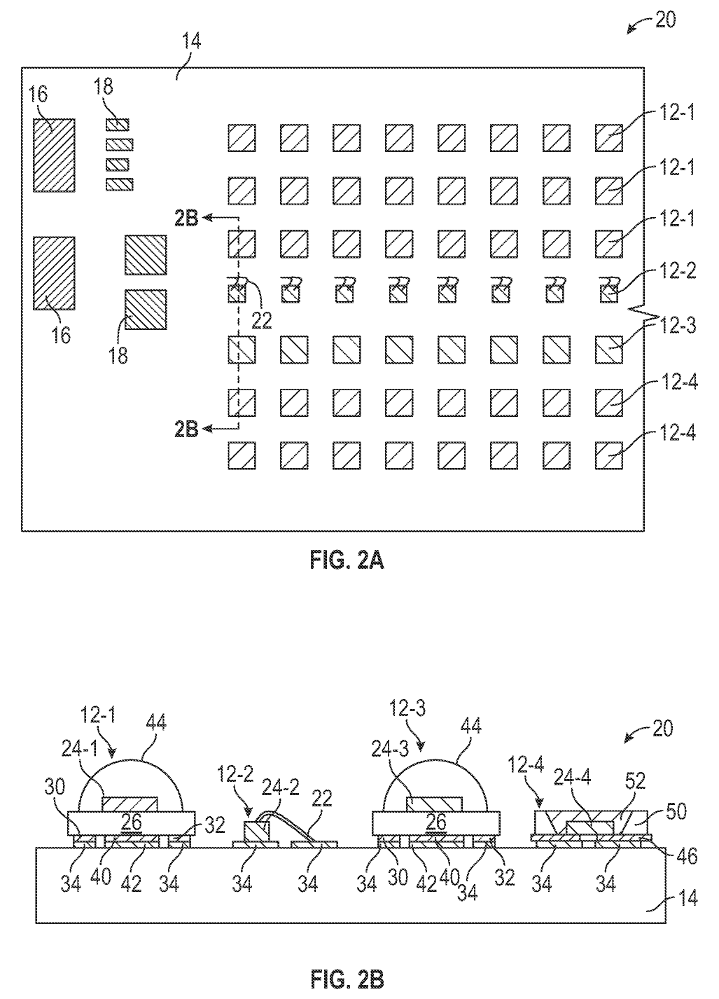

FIG. 2A is a top view of an LED device 20 that is similar to the LED device 10 for embodiments where certain LED emitters 12-2 embody LED chips that are mounted to the submount 14 without packaging. In certain aspects, the LED emitters 12-2 may be electrically coupled to the submount 14 by way of one or more wire bonds 22. FIG. 2B is a cross-sectional view of a portion of the LED device 20 of FIG. 2A taken along the sectional line 2B-2B of FIG. 2A.

As best illustrated in FIG. 2B, each of the LED emitters 12-1 to 12-4 include corresponding LED chips 24-1 to 24-4. The LED emitters 12-1, 12-2, and 12-4 embody LED packages. For example, the LED emitters 12-1 and 12-3 include corresponding package submounts 26 and package bonding pads 30, 32. The package bonding pads 30, 32 form anode and cathode connections that are mounted and electrically coupled to corresponding electrically conductive traces 34 of the submount 14. For embodiments where the LED emitters 12-1 to 12-4 are separately controllable, the corresponding pairs of traces 34 for each LED emitter 12-1 to 12-4 may be separately connected to the LED driver formed by the one or more semiconductor devices 18 of FIG. 2A. In certain embodiments, the LED emitters 12-1 and 12-3 may include a thermal pad 40 that is mounted and thermally connected to a corresponding electrically conductive trace 42 of the submount 14. Each of the LED emitters 12-1 and 12-3 may further include a lens 44 configured to direct light in targeted emission patterns. In certain embodiments, the LED emitters 12-4 may form LED packages with different structures than the LED emitters 12-1 and 12-3. For example, the LED emitters 12-4 may comprise lead frames 46 with corresponding housings 50. A portion of the housing 50 may form a recess that is filled with a lumiphoric material 52, such as phosphor particles intermixed in a binder material. Aggregate emissions from the LED emitter 12-4 may include wavelengths generated by the LED chip 24-4 and wavelengths generated by wavelength conversion from the lumiphoric material 52. In certain embodiments for horticulture applications, the wavelength-converted light from the LED emitters 12-4 may provide ambient lighting while the specific peak wavelengths of the other LED emitters 12-1 to 12-3 may provide targeted chlorophyll absorption peaks, and each of the LED emitters 12-1 to 12-4 may be independently activated and deactivated based on the target crop and corresponding growth conditions.

As illustrated in FIG. 2B, the LED emitters 12-2 may comprise the LED chip 24-2 in the form of bare chips or die that are directly mounted to the submount 14 without intervening packaging elements, such as lead frames with housings or submounts of LED packages. When the LED chip 24-2 has a vertical structure, the LED chip 24-2 may be mounted and electrically coupled to one trace 34 and electrically coupled to the other corresponding trace 34 by way of the wire bond 22. In comparison to the other LED chips 24-1, 24-3, 24-4 that reside in LED packages, the LED chip 24-2 is directly connected to the submount 14. In this manner, additional thermal interfaces attributed to the submount 26 or the lead frame 46 of the other LED packages are avoided, thereby improving heat dissipation for the LED emitter 12-2 while also reducing associated costs. In certain instances, the active LED structure of the LED chip 24-2 may be formed with a material structure that provides red wavelengths of light that are known to exhibit increased thermal droop compared with blue-emitting LED chips. With increased thermal dissipation to the submount 14, the LED emitters 12-2 may be operated with increased efficiency. In certain embodiments, the LED emitters 12-1 may form LED packages that also provide red wavelengths. Accordingly, some red light from the LED emitter 12-1 may be shaped by the corresponding lens 44 and other red light from the LED emitter 12-2 may provide an emission profile based on the LED chip 24-2 itself. The ability to mix emission profiles from lensed LED chips (e.g., 24-1, 24-3) and un-lensed LED chips (e.g., 24-2) advantageously allows dynamic shaping of emission patterns by changing current flow through different strings of the LED emitters 12-1 to 12-4.

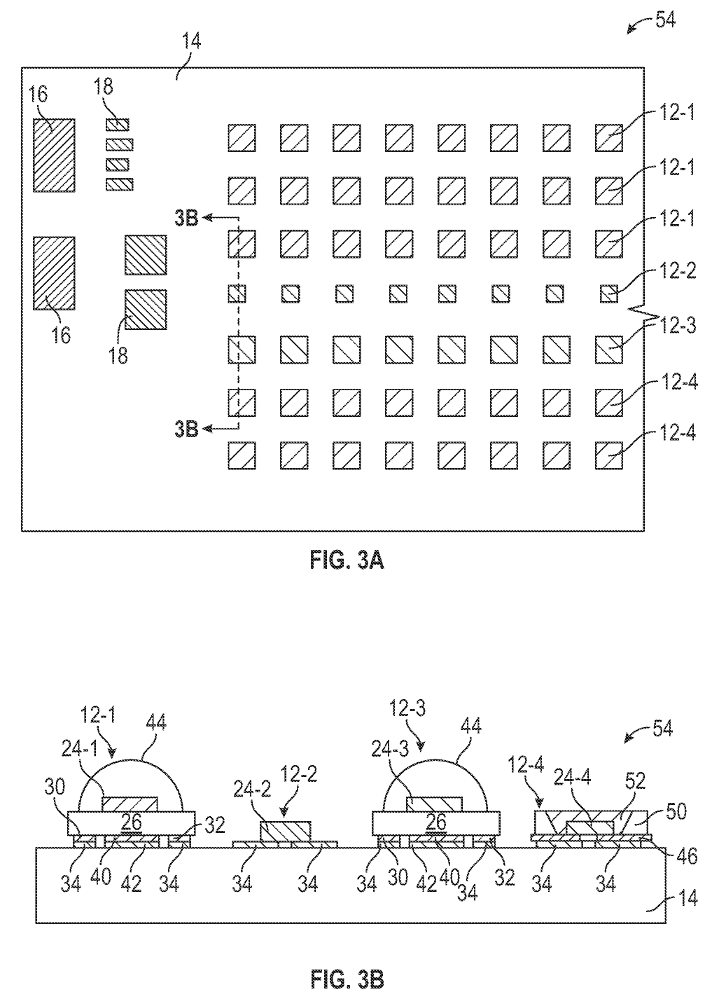

FIG. 3A is a top view of an LED device 54 that is similar to the LED device 20 of FIGS. 2A and 2B for embodiments where the LED emitters 12-2 embody LED chips that are flip-chip mounted to the submount 14 without packaging. FIG. 3B is a cross-sectional view of a portion of the LED device 54 of FIG. 3A taken along the sectional line 3B-3B of FIG. 3A. As illustrated, the LED chip 24-2 may be flip-chip mounted to corresponding traces 34 of the submount 14. Such an arrangement avoids positioning wire bonds in the primary light emission direction for the LED emitter 12-2. Moreover, a flip-chip structure for the LED chip 24-2 may generate a different emission pattern than the vertical structure of FIG. 2B for different applications.

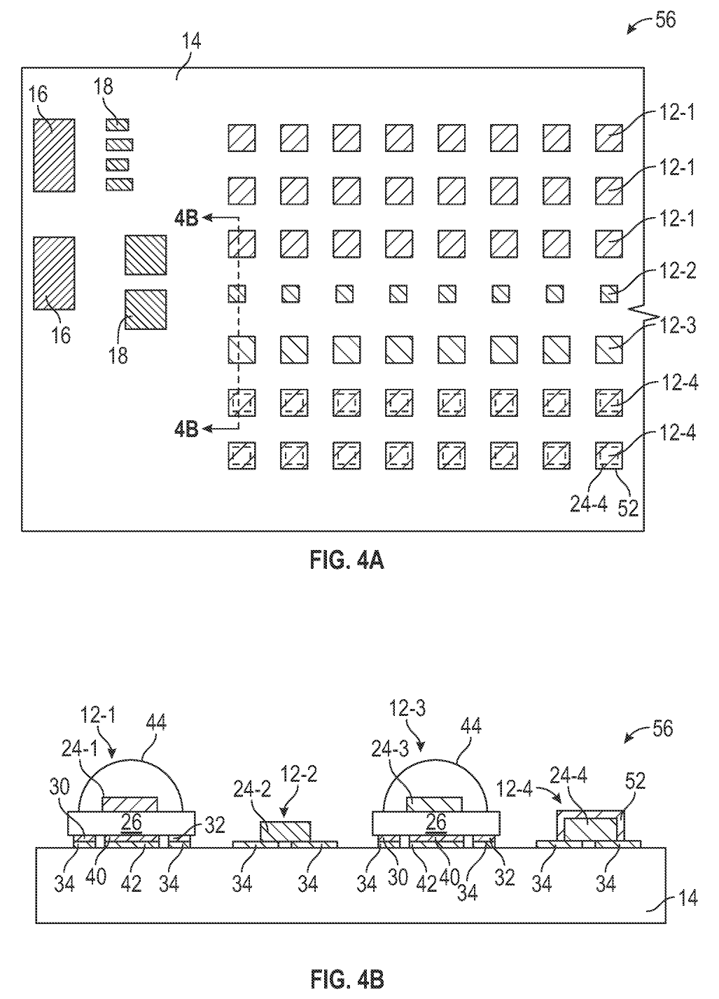

FIG. 4A is a top view of an LED device 56 that is similar to the LED device 54 of FIGS. 3A and 3B for embodiments where both the LED emitters 12-2 and 12-4 embody LED chips mounted to the submount 14 without packaging. FIG. 4B is a cross-sectional view of a portion of the LED device 56 of FIG. 4A taken along the sectional line 4B-4B of FIG. 4A. In a similar manner as the LED chip 24-2, the LED chip 24-4 of the LED emitter 12-4 forms a bare chip or die that is directly mounted to the submount 14 without intervening packaging elements, such as lead frames with housings or submounts of LED packages. The lumiphoric material 52 may be formed as part of the LED chip 24-4 before mounting. Alternatively, the lumiphoric material 52 may be formed on the LED chip 24-4 after mounting. As best illustrated in FIG. 4A, each LED chip 24-4 may be formed with a discrete lumiphoric material.

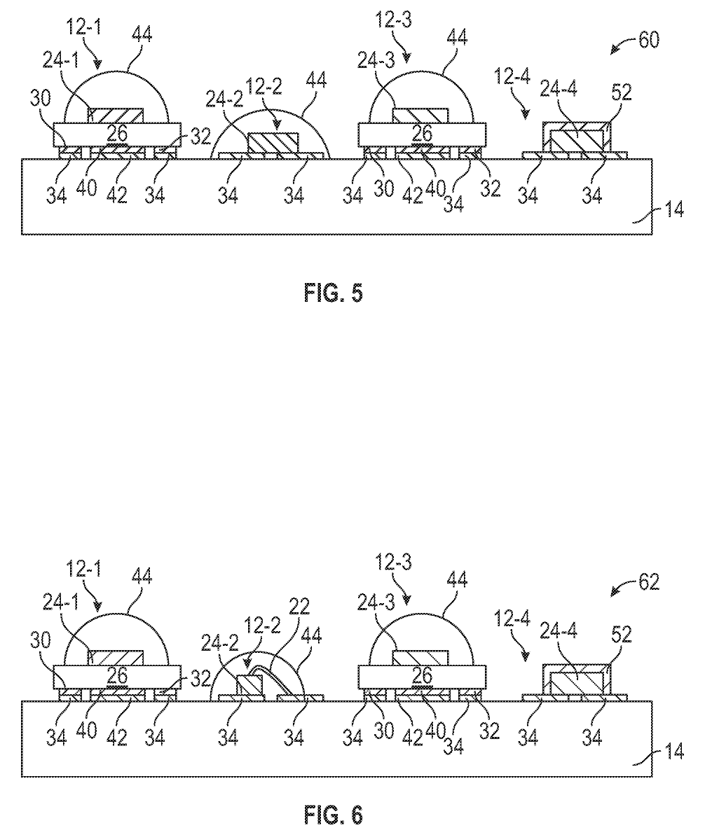

FIG. 5 is a cross-sectional view of an LED device 60 that is similar to the LED device 56 of FIGS. 4A and 4B for embodiments where at least one of the LED emitters 12-2 further includes the lens 44. Since the LED chip 24-2 of the LED emitter 12-2 is a bare LED chip mounted to the submount 14 without packaging, the lens 44 for the LED emitter 12-2 may be directly positioned on the submount 14. For example, the lens 44 of the LED emitter 12-2 may cover the LED chip 24-2 and one or more portions of the corresponding traces 34, and the lens 44 may further extend on potions of the submount 14 that are laterally adjacent the LED chip 24-2. In one example, the lens 44 for the LED emitter 12-2 may be directly molded or dispensed to the submount 14. In another example, the lens 44 for the LED emitter 12-2 may embody a pre-formed structure that is subsequently attached to the submount 14.

FIG. 6 is a cross-sectional view of an LED device 62 that is similar to the LED device 60 of FIG. 5 for embodiments where the LED chip 24-2 has a vertical chip structure. Instead of the flip-chip arrangement of FIG. 5, the LED chip 24-2 for FIG. 6 is mounted and electrically coupled to one of the traces 34, and electrical connections to the other trace 34 is facilitated by way of the wire bond 22. In certain embodiments, the lens 44 may encapsulate the wire bond 22 for added protection. As illustrated, the lens 44 may not cover all of the corresponding traces 34 to which the LED chip 24-2 is electrically connected. It is understood the traces 34 may extend to connect with other arrays of the LED chip 24-2 in multiple chip embodiments.

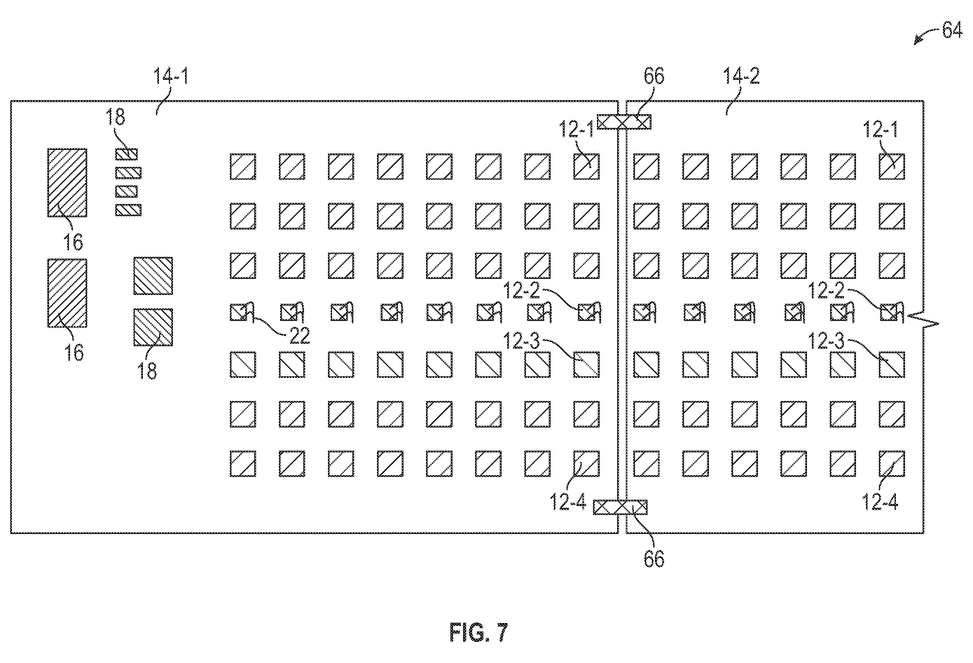

FIG. 7 is a top view of an LED device 64 that is similar to the LED device 20 of FIGS. 2A and 2B for embodiments that include multiple submounts 14-1, 14-2. In certain embodiments, LED emitters 12-1 to 12-4 may be populated on multiple submounts 14-1, 14-2 for a modular structure. By way of example, the first submount 14-1 may be electrically coupled to the second submount 14-2 by way of one or more electrical connections 66, such as jumpers, that extend between the two submounts 14-1, 14-2. In certain embodiments, each array of LED emitters 12-1 to 12-4 may span across both submounts 14-1, 14-2. By way of example, the array of LED emitters 12-1 may be electrically coupled together in one or more strings that extend across both submounts 14-1, 14-2. Similar arrangements may be provided for the other LED emitters 12-2 to 12-4. In certain embodiments, the electrical connectors 16 and the LED driver formed by the semiconductor devices 18 may only need to be on one of the submounts (e.g., 14-1). While the LED device 64 is described with LED emitters 12-1 to 12-4 that are similar to FIGS. 2A and 2B, the principles described are equally applicable to any of the other arrangements of the LED emitters 12-1 to 12-4 as described for FIGS. 3A-6.

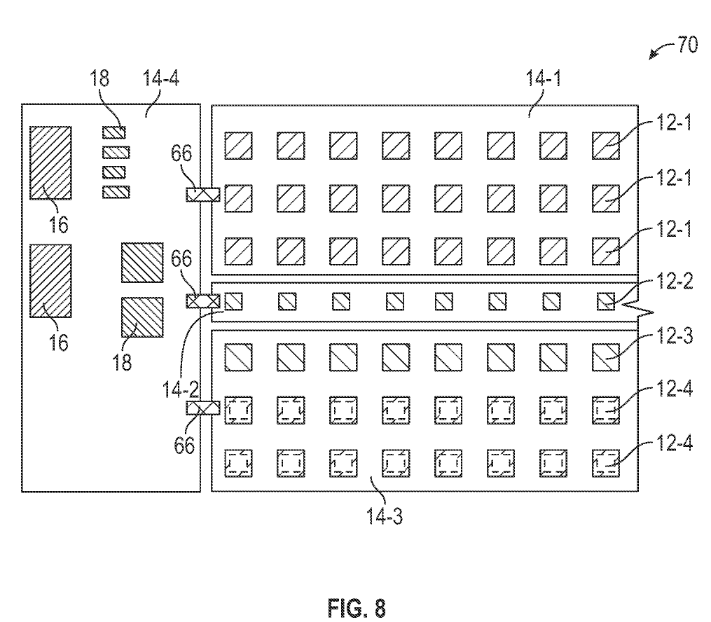

FIG. 8 is a top view of an LED device 70 that is similar to the LED device 64 of FIG. 7 with another arrangement of multiple submounts 14-1 to 14-4. For the LED device 70, the electrical connectors 16 and the LED driver formed by the semiconductor devices 18 reside on the submount 14-4, the LED emitters 12-1 reside on the submount 14-1, the LED emitters 12-2 reside on the submount 14-2, and the LED emitters 12-3 and 12-4 reside on the submount 14-3. In this manner, the LED emitters 12-1 to 12-4 are grouped together on corresponding submounts 14-1 to 14-4 based on one or more of emission characteristics and/or electrical driving requirements. For example, red LED chips, such as those present for the LED emitters 12-1 and 12-2, are known to have different turn-on voltages than blue LED chips, such as those present for the LED emitters 12-3 and 12-4. Accordingly, different drive voltages may be routed to the submounts 14-1 to 14-3. Moreover, the submounts 14-1 to 14-3 may be differentiated by emission characteristics and/or package structures of the corresponding LED emitters 12-1 to 12-3. For example, the LED emitters 12-2 with bare LED chips may reside on their own submount 14-2. Accordingly, the LED device 70 may be structured in a modular manner with different arrangements of submounts 14-1 to 14-4 depending on the target application. Additionally, while the electrical connectors 16 and the LED driver formed by the semiconductor devices 18 are shown on their own submount 14-4, they may alternatively be positioned on any of the other submounts 14-1 to 14-3. The principles described for FIG. 8 are equally applicable to any of the other arrangements of the LED emitters 12-1 to 12-4 as described for FIGS. 2A-6.

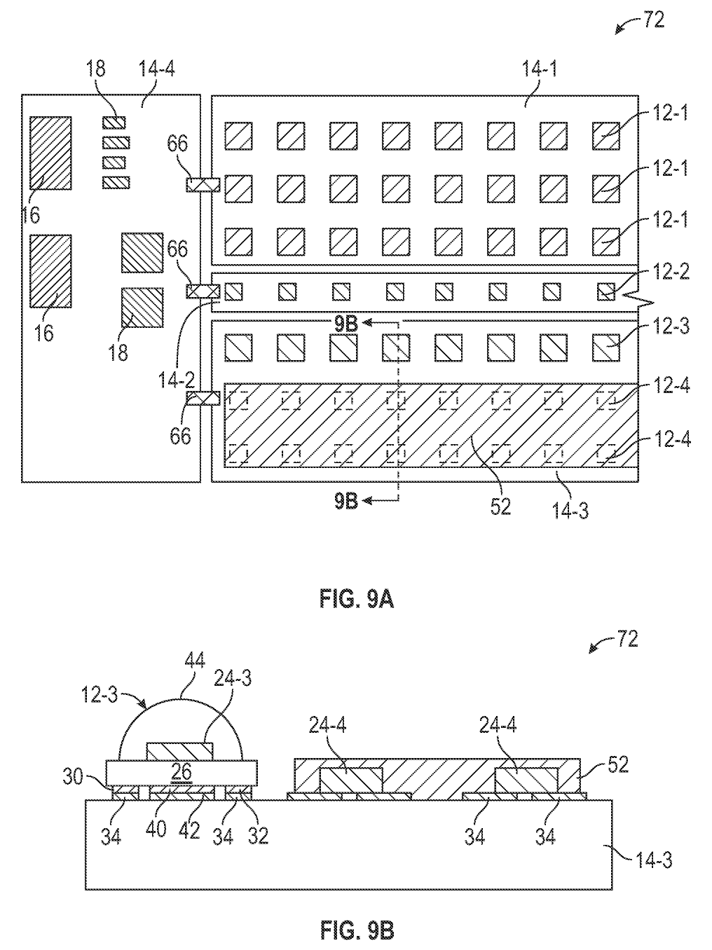

FIG. 9A is a top view of an LED device 72 that is similar to the LED device 70 of FIG. 8 for embodiments where the lumiphoric material 52 extends across multiple ones of the LED emitters 12-4. FIG. 9B is a cross-sectional view of a portion of the LED device 72 of FIG. 9A taken along the sectional line 9B-9B of FIG. 9A. As illustrated, the LED chips 24-4 of the LED emitters 12-4 embody bare LED chips mounted to the submount 14-3 without package structures such as intervening submounts or lead frames. Once the LED chips 24-4 are mounted to the submount 14-3, the lumiphoric material 52 may be formed in a continuous manner to cover each LED chip 24-4. In certain embodiments, this arrangement may provide a more uniform emission pattern for wavelength-converted light, such as when used as ambient lighting for horticulture applications. The principles described for FIGS. 9A and 9B, such as the continuous nature of the lumiphoric material 52, are equally applicable to any of the other arrangements of the LED emitters 12-1 to 12-4 as described for FIGS. 2A-6.

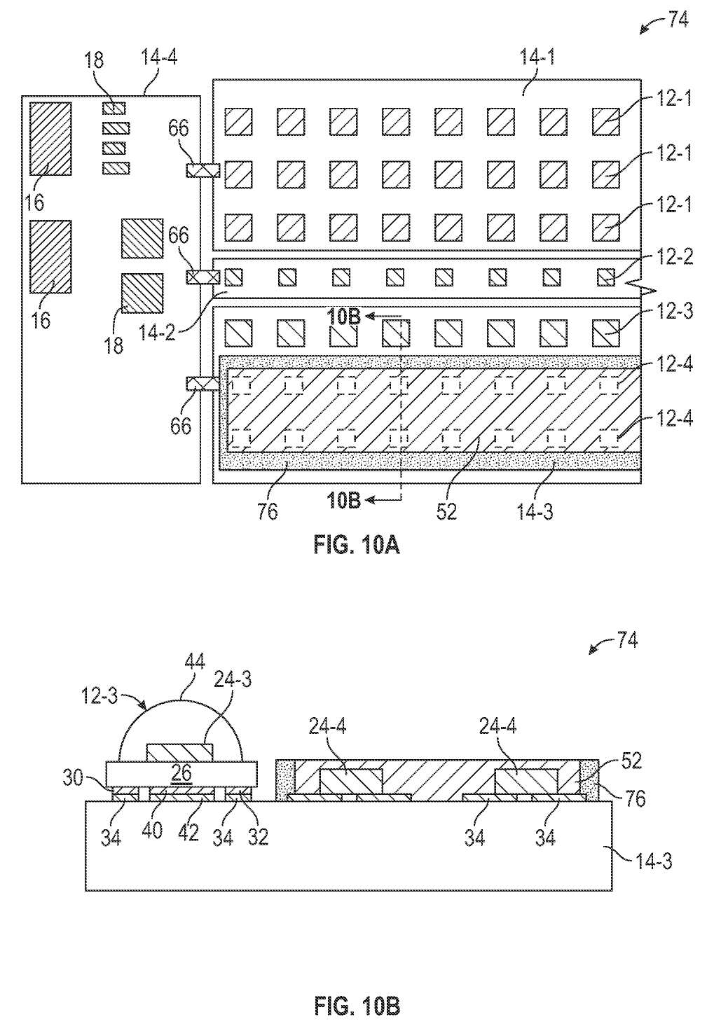

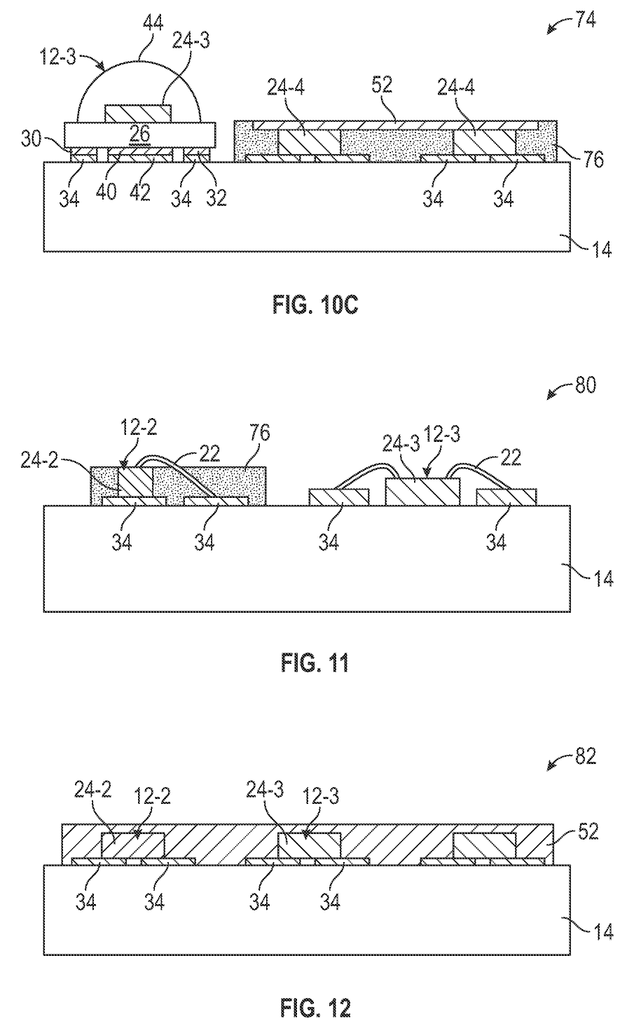

FIG. 10A is a top view of an LED device 74 that is similar to the LED device 72 of FIGS. 9A and 9B for embodiments that further include a light-altering material 76. FIG. 10B is a cross-sectional view of a portion of the LED device 74 of FIG. 10A taken along the sectional line 10B-10B of FIG. 10A. The light-altering material 76 may form a light-reflective material that laterally surrounds a perimeter of the lumiphoric material 52 and the LED emitters 12-4. In this manner, laterally propagating light within the lumiphoric material 52 may be redirected to exit in a desired emission direction, thereby reducing lateral emissions that interact with neighboring LED emitters 12-1 to 12-3. In certain embodiments, the light-altering material 76 may first be formed on the submount 14-3 to form a dam for retaining the subsequently formed lumiphoric material 52.

FIG. 10C is a cross-sectional view of a portion of the LED device 74 of FIG. 10A taken along the sectional line 10B-10B of FIG. 10A for an alternative arrangement of the light-altering material 76 and the lumiphoric material 52. For FIG. 10C, the lumiphoric material 52 may embody a pre-formed structure, such as a transparent substrate with a coating of the lumiphoric material 52, or a phosphor-in-glass structure, or a ceramic phosphor plate, or a single crystal phosphor, or a sheet of lumiphoric material that is pre-formed and singulated. The light-altering material 76 may be first formed along the LED chips 24-4 followed by placement of the lumiphoric material 52. In certain embodiments, the light-altering material 76 may serve to adhere at least a portion of the lumiphoric material 52 in place.

The principles described for FIGS. 10A-10B, such as the structure of the light-altering material 76 relative to the lumiphoric material 52, are equally applicable to any of the other arrangements of the LED emitters 12-1 to 12-4 as described for FIGS. 2A-6.

FIG. 11 is a cross-sectional view of a portion of an LED device 80 that is similar to the LED device 20 of FIGS. 2A and 2B for embodiments where the light-altering material 76 is provided to laterally surround perimeter edges of the LED chips 24-2 that emit red light. Since the LED chips 24-2 embody bare LED chips mounted to the submount 14, the light-altering material 76 may be formed proximate the LED chips 24-2 after the LED chips 24-2 are mounted. In certain embodiments, particularly where the LED chips 24-2 emit red light, such as having a peak wavelength in a range from 630 nm to 780 nm, the LED chips 24-2 may embody topside emitters where light is primarily emitted from the top surfaces thereof. By positioning the light-altering material 76 along perimeter edges or sidewalls of the LED chip 24-2, more light is directed through the topside and reduced amounts of lateral light may escape that would otherwise interact with neighboring LED emitters (e.g., the LED emitter 12-3 or additional LED emitters 12-2) and potentially be lost to absorption. In certain embodiments, the traces 34 for the LED emitter 12-3 may embody a reflective sticker, such as a reflective silver (Ag) sticker, that has increased thickness relative to other traces 34 for increased redirection of laterally propagating light from the LED chip 24-3. The principles described for FIG. 11, such as the structure of the light-altering material 76 relative to the LED chip 24-2, or the increased thickness of the traces 34 for the LED chip 24-3, are equally applicable to any of the other arrangements of the LED emitters 12-1 to 12-4 as described for FIGS. 2A - 10C.

FIG. 12 is a cross-sectional view of a portion of an LED device 82 that is similar to the LED device 72 of FIGS. 9A and 9B for embodiments where the lumiphoric material 52 extends to cover the LED chip 24-2. In certain embodiments, the peak wavelength generated by the LED chip 24-2, such as a red peak wavelength, may be sufficiently outside the excitation spectrum of the lumiphoric material 52 so that the red light may freely pass through the lumiphoric material 52. In this manner, the LED chips 24-2 and 24-3 may both reside underneath the lumiphoric material 52 and an aggregate emission color or spectral content of overall light exiting the lumiphoric material 52 may be adjusted by selectively controlling the LED chip 24-2 relative to the LED chip 24-3. The principles described for FIG. 12, such as the structure of the lumiphoric material 52, is equally applicable to any of the other arrangements of the LED emitters 12-1 to 12-4 as described for FIGS. 2A-11.

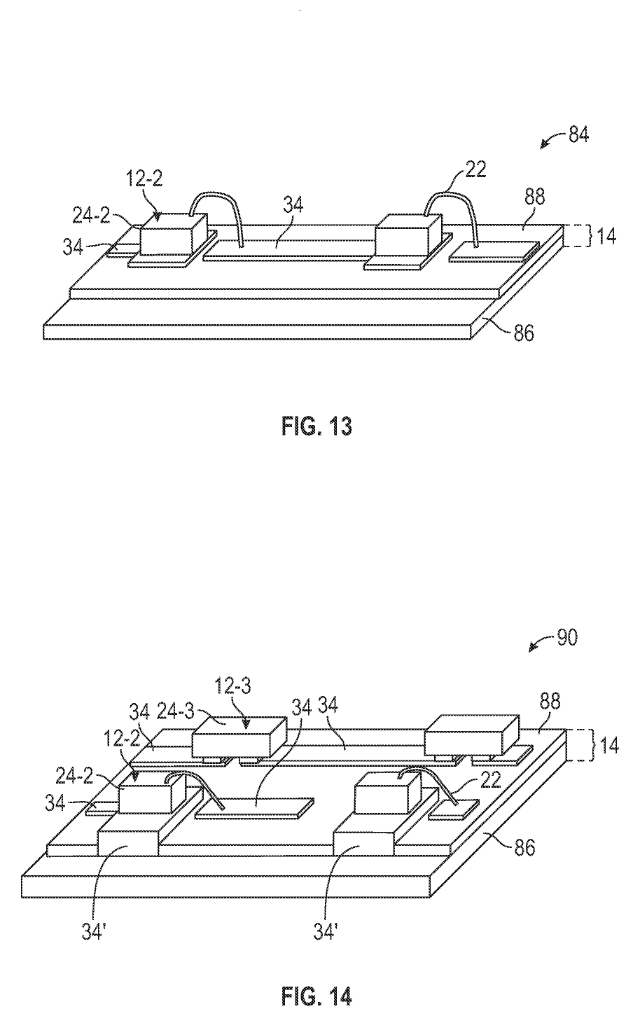

FIG. 13 is a top perspective view of an LED device 84 similar to the LED device 20 of FIGS. 2A and 2B for embodiments where the submount 14 comprises a printed circuit board with a metal core 86 and a top dielectric layer 88. In certain structures, the metal core 86 may also form a bottom of the submount 14. The traces 34 may be patterned on the dielectric layer 88 and electrically isolated from the metal core 86. Such an arrangement may be provided for any of the submounts 14 described above for FIGS. 1-12.

FIG. 14 is a top perspective view of an LED device 90 similar to the LED device 84 of FIG. 13 for embodiments where at least one of the traces 34 forms a direct electrical and thermal path to the metal core 86. By way of example, the LED chips 24-2 form bare LED chips mounted to corresponding traces 34, and a portion of each trace 34’ forms part of a direct thermal and electrical path through the dielectric layer 88 to the metal core 86. In this manner, the portions of each trace 34’ provide a continuous electrical and thermal pathway from the LED chips 24-2 to the metal core 86 that avoids dielectric interfaces. Accordingly, the LED chips 24-2 are provided with increased thermal dissipation to permit enhanced thermal performance. In the context of the LED chips 24-2 comprising red LED chips, this is advantageous for reducing problems of thermal droop. In such an arrangement, all of the LED chips 24-2 may be electrically coupled in parallel and the metal core 86 is electrically active. Other LED emitters (e.g., 24-3 of FIG. 14), may remain electrically coupled to traces 34 on the top of the dielectric layer 88 that are electrically isolated from the metal core 86. Such an arrangement may be provided for any of the submounts 14 described above for FIGS. 1-12 to provide increased thermal performance for the LED chips 24-2.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device comprising:
a submount comprising a printed circuit board;
a first LED emitter on the submount, the first LED emitter comprising an LED package with a first LED chip configured to provide light having a first peak wavelength; and
a second LED emitter on the submount, the second LED emitter comprising a second LED chip that forms a bare LED chip mounted to the submount, the second LED chip configured to provide light having a second peak wavelength that is different than the first peak wavelength, the first peak wavelength and the second peak wavelength being in a range from 630 nanometers (nm) to 780 nm.

2. The LED device of claim 1, further comprising:
an LED driver on the submount, the LED driver configured to electrically activate the first LED emitter and the second LED emitter independently of one another; and
one or more electrical connectors on the submount, the one or more electrical connectors configured to receive an external electrical connection for the LED driver.

3. The LED device of claim 1, wherein the LED package of the first LED emitter comprises a lens configured to provide a first emission pattern that is different from a second emission pattern provided by the second LED emitter.

4. The LED device of claim 1, wherein the first LED emitter comprises package bonding pads bonded to the submount, and the second LED emitter comprises at least one wire bond bonded between the second LED chip and the submount.

5. The LED device of claim 1, wherein the first LED emitter comprises package bonding pads bonded to the submount, and the second LED chip of the second LED emitter is flip-chip mounted to the submount.

6. The LED device of claim 1, further comprising:
a third LED emitter on the submount, the third LED emitter comprising an LED package with a third LED chip configured to provide light having a third peak wavelength that is different than the first peak wavelength and the second peak wavelength; and
a fourth LED emitter on the submount, the fourth LED emitter comprising an LED package with a fourth LED chip and a lumiphoric material.

7. The LED device of claim 1, further comprising:
a third LED emitter on the submount, the third LED emitter comprising an LED package with a third LED chip configured to provide light having a third peak wavelength that is different than the first peak wavelength and the second peak wavelength; and
a fourth LED emitter on the submount, the fourth LED emitter comprising a fourth LED chip mounted to the submount and a lumiphoric material on the fourth LED chip.

8. The LED device of claim 1, further comprising a third LED emitter on the submount, the third LED emitter comprising a third LED chip mounted to the submount and a lumiphoric material on the third LED chip, the lumiphoric material being positioned to cover the third LED emitter and the second LED emitter.

9. The LED device of claim 1, further comprising a lens on the second LED chip and on a portion of the submount laterally adjacent the second LED chip.

10. The LED device of claim 1, further comprising a light-altering material on the submount and laterally surrounding a perimeter of the second LED chip, the light-altering material comprising a light-reflective material.

11. The LED device of claim 1, wherein the printed circuit board comprises a metal core and a dielectric layer on the metal core, wherein the second LED chip is mounted and electrically coupled to a trace of the printed circuit board, the trace forming part of a direct thermal and electrical path through the dielectric layer to the metal core.

12. A light-emitting diode (LED) device comprising:
a first printed circuit board;
a second printed circuit board;
a plurality of first emitters on at least one of the first printed circuit board and the second printed circuit board, each first emitter of the plurality of first emitters comprising an LED package with a first LED chip configured to provide light having a first peak wavelength; and
a plurality of second emitters on at least one of the first printed circuit board and the second printed circuit board, each second emitter of the plurality of second emitters comprising a second LED chip that forms a bare LED chip mounted to the at least one of the first printed circuit board and the second printed circuit board, the second LED chip configured to provide light having a second peak wavelength that is different than the first peak wavelength, the first peak wavelength and the second peak wavelength being in a range from 630 nanometers (nm) to 780 nm.

13. The LED device of claim 12, further comprising an LED driver configured to drive the plurality of first emitters and the plurality of second emitters.

14. The LED device of claim 13, wherein the LED driver is positioned on the first printed circuit board and the LED driver is electrically coupled to the second printed circuit board by at least one electrical connection that extends between the first printed circuit board and the second printed circuit board.

15. The LED device of claim 12, wherein:
the plurality of first emitters forms an array of the first emitters that extends across the first printed circuit board and the second printed circuit board; and
the plurality of second emitters forms an array of the second emitters that extends across the first printed circuit board and the second printed circuit board.

16. The LED device of claim 12, wherein the plurality of first emitters are only on the first printed circuit board and the plurality of second emitters are only on the second printed circuit board.

17. The LED device of claim 12, further comprising a third printed circuit board and a plurality of third emitters that are only on the third printed circuit board, wherein each third emitter of the plurality of third emitters comprises a third LED chip with a turn-on voltage that is different than turn-on voltages of the plurality of first emitters and the plurality of second emitters.

18. The LED device of claim 17, further comprising a plurality of fourth LED emitters on the third printed circuit board, each fourth LED emitter of the plurality of fourth LED emitters comprising a fourth LED chip mounted to the submount and a lumiphoric material on the fourth LED chip, fourth LED chip have the same turn-on voltage as the third LED chip.

19. The LED device of claim 18, wherein the lumiphoric material covers the plurality of fourth LED emitters on the third printed circuit board.

20. The LED device of claim 19, further comprising a light-altering material that laterally surrounds a perimeter of the lumiphoric material on the third printed circuit board.
